(19) United States
(12) Patent Application Publication
(10) Pub. No.: US 2002/0060358 A1
(43) Pub. Date: May 23, 2002

(54) Package of an image sensor device

(76) Inventors: Chin-Yuan Hung, Taichung Hsien (TW); Lien-Chen Chiang, Taichung (TW); Cheng-Shiu Hsiao, Nantou (TW)

Correspondence Address: J.C. Patents, Inc., 4 Venture, Suite 250, Irvine, CA, 92618, US

(21) Appl. No.: 09/841,855

(22) Filed: Apr. 25, 2001

(30) Foreign Application Priority Data
Nov. 17, 2000 (TW) 89124358

(51) Int. Cl. H01L 23/02

(52) U.S. Cl. 257/678

(57) ABSTRACT

The present invention provides a package comprising a lead frame, which has a die pad and a plurality of leads located at the peripheral of the die pad. An image sensor chip has an active surface and a corresponding back surface. A plurality of bonding pads are on the active surface. A plurality of leads are electrically connected from the bonding pads to the inner leads. The image sensor chip, the die pads and the inner leads are encapsulated with a transparent molding material. A cavity is formed on a surface of the transparent molding material corresponding to the active surface. The area of the cavity, which is large enough just to cover the chip of the image sensor, has a smooth surface after a polishing process.

### CROSS REFERENCE TO RELATED APPLICATION

This application claims the priority benefit of Taiwan application Ser. No. 89124358, filed Nov. 17, 2000.

### BACKGROUND OF THE INVENTION

1. Field of the Invention

The present invention relates to a package of a semiconductor device. More particularly, the present invention relates to a package of an image sensor device.

2. Description of the Related Art

A package process of a semiconductor device is the process after completing the first part of fabricating a semiconductor device. The package process separates each chip of the wafer, and connects the chip to a lead frame by a wire bonding method. A resin material is used to encapsulate the chip and lead frame, and an outer lead is exposed for an outer connection. In view of different functional requirements, during the first part of the process of fabricating a semiconductor device, the surface of each layer of the chip will have different circuit pattern designs and a different number of bonding pads.

In view of the requirements of photology, the image sensor device has to use a transparent molding method. The molding surface that corresponds to an active surface of the chip needs to be polished in order to prevent the light that passes through the molding surface from deflecting on the active surface of the chip.

In the conventional method, the polished surface of the package of the image sensor chip is not well protected. Therefore after the molding process and during any step of the fabrication, if the polished surface comes into contact with anything, it will be damaged and abraded, and its transparency will be affected. Therefore, the conventional package has the disadvantage of abrading the polished surface and less light will be able to transmit through the device.

Referring to FIG. 1 and FIG. 2, FIG. 1 is a schematic diagram of a conventional package of an image sensor device, and FIG. 2 is a schematic top view of the conventional package of the image sensor device of FIG. 1. Some parts of the device and some reference numbers of FIG. 1 are not shown in FIG. 2, so that the main structure of the device can be seen easily. A back surface 108b of a chip 108 of the image sensor device is adhered on a die pad 100 of a lead frame 102. A bonding pad 107 of the image sensor chip 108 is connected to an inner lead 102b of the lead frame 102 by conductive wires 106. The image sensor chip 108, the die pad 100, and the inner lead 102b are encapsulated with a transparent molding material 110 to complete a package body of the image sensor 111. Due to the requirements of photology, a molding surface 112 corresponding to an active surface 108a of the image sensor chip 108 must be polished. The polishing process prevents the light that passes through the molding surface 112 from deflecting on the active surface 108a.

FIG. 3 is a schematic diagram of an image sensor chip for a post mold cure (PMC) process after completing a molding process. FIG. 4 is a schematic magnified diagram of a region 116 of FIG. 3. During the PMC process, the package of the image sensor chip 111 is stacked up with each other to save space. This method will cause the polished surface 112 to have some abraded defects. FIG. 4 shows a magnified portion of the contact part of the region 116. Some abraded defects 112a occur on the molding surface 112. When an incident light 118 radiates onto the abraded defect 112a, a refracted light 120 will be produced and the light transmitted to the active surface 108a of the chip 108 will be reduced.

### SUMMARY OF THE INVENTION

The present invention of a package of an image sensor device provides a solution to the above-mentioned problem of the prior art. The package of the present invention comprises a lead frame, at least one die pad and a plurality of leads that are located at the peripheral of the die pad. Each lead has an inner lead and an outer lead. An image sensor chip has an active surface and a corresponding back surface. A plurality of bonding pads are on the active surface. The back surface of the chip is adhered on the die pad. A plurality of conductive wires are electrically connected from the bonding pads to the inner leads. The image sensor chip, the die pads and the inner leads are encapsulated with a transparent molding material. A cavity is formed on a surface of the transparent molding material corresponding to the active surface. The area of the cavity is large enough just to cover the chip of the image sensor, and a bottom surface of the cavity is a smooth surface after a polishing process.

The present invention also provides another package of an image sensor device that comprises a lead frame, at least one die pad and a plurality of leads located at the peripheral of the die pad. Each lead has an inner lead and an outer lead. An image sensor chip has an active surface and a corresponding back surface. A plurality of bonding pads are on the active surface. The back surface of the chip is adhered on the die pad. A plurality of conductive wires are electrically connected from the bonding pads to the inner leads. The image sensor chip, the die pads and the inner leads are encapsulated with a transparent molding material. A smooth surface that has been polished is formed on a surface of the transparent molding material corresponding to the active surface. The smooth surface partially covers the chip of the image sensor and a protrusion is installed at the periphery of the smooth surface.

The characteristic of the present invention is to use a cavity surface or a protrusion of a transparent molding surface to prevent coming into direct contact with the polished surface of the molding surface. When the polished surface is defected, less light will be transmitted to the active surface of the chip, and light transmission therefore will be reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic diagram of a package of an image sensor device of the prior art;

FIG. 2 is a schematic top view of FIG. 1;

FIG. 3 is a schematic diagram of a package of an image sensor device for a post mold cure (PMC) process after completing a molding process;

FIG. 4 is a schematic magnified diagram of region 116 of FIG. 3;

FIG. 5 is a schematic diagram of a package of an image sensor device according to a first preferred embodiment of the present invention;

FIG. 6 is a schematic top view of FIG. 5;

FIG. 7 is a schematic diagram of a package of an image sensor device for a post mold cure (PMC) process after completing a molding process according to a first preferred embodiment of the present invention;

FIG. 8 is a schematic diagram of a package of an image sensor device according to a second preferred embodiment of the present invention;

FIG. 9 is a schematic top view of FIG. 8;

FIG. 10 is a schematic diagram of a strip-shaped protrusion on the transparent molding surface of a package of an image sensor device; and

FIG. 11 is a schematic diagram of a ring-shaped protrusion on the transparent molding surface of a package of an image sensor device.

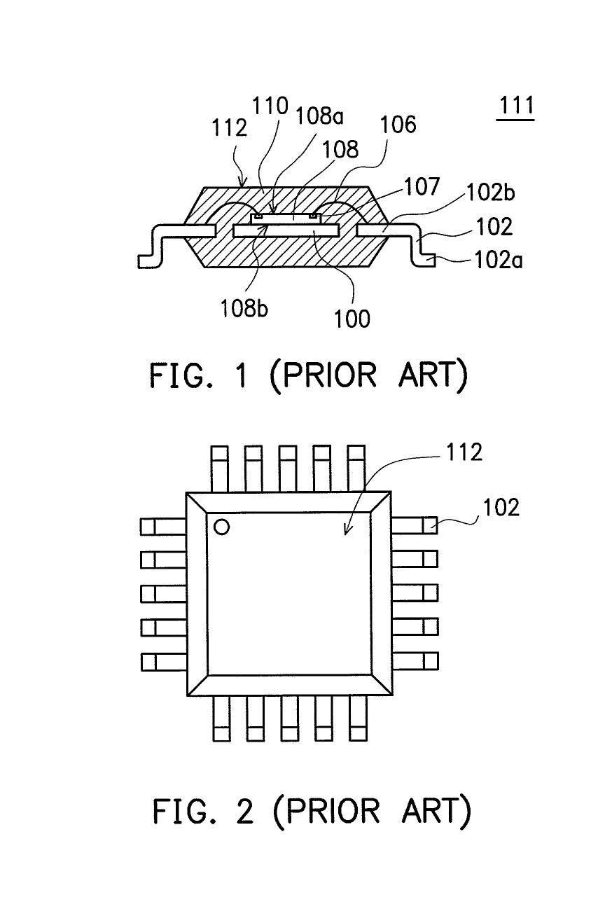

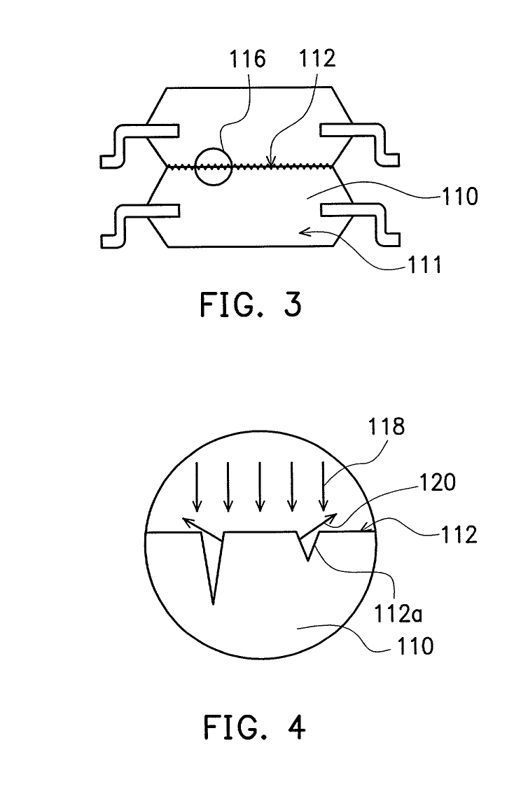

### DESCRIPTION OF THE PREFERRED EMBODIMENTS

First Preferred Embodiment

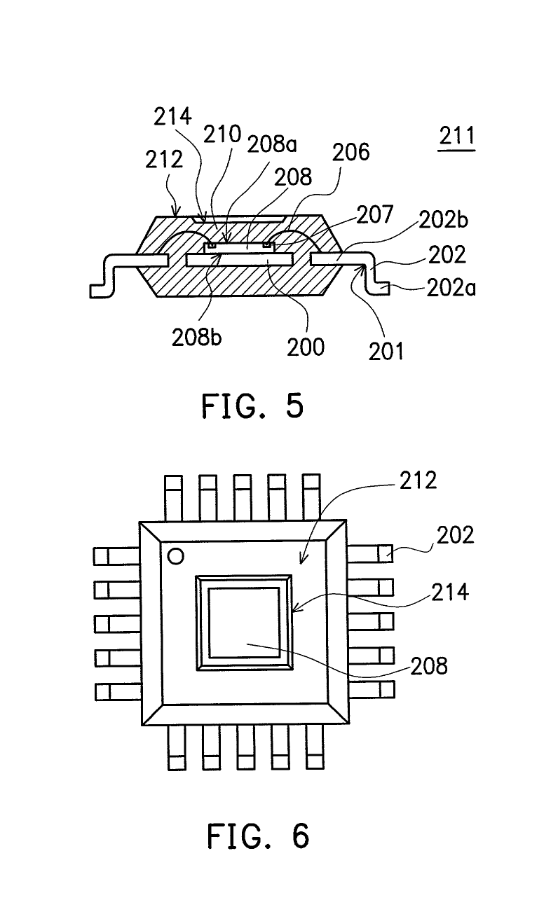

Referring to FIG. 5 and FIG. 6. FIG. 5 is a schematic diagram of a package of an image sensor device of a first preferred embodiment according to the present invention. FIG. 6 is a schematic top view of FIG. 5. Some parts of the device and reference numbers are not shown in FIG. 6, so that the main structure of the device can be seen easily. At least one die pad 200 is in a lead frame 201, a plurality of leads 202 are located at periphery of the die pad 200. Each lead 202 has an inner lead 202b and an outer lead 202a. An image sensor chip 208 has an active surface 208a and a corresponding back surface 208b. The back surface 208b of the chip is adhered on the die pad 200. The chip of the image sensor device 208 is a complementary metal-oxide semiconductor (CMOS), for example.

A plurality of bonding pads 207 are formed on the active surface 208a of the image sensor chip 208. The bonding pads 207 are electrically connected to the inner lead 202b of the lead 202 by conductive wires 206. The image sensor chip 208, the die pad 200 and the inner lead 202b of the leads 202 are encapsulated by a transparent material 210, for example a transparent resin. The package of the image sensor device is thus completed. The surface 212 of the transparent material 210 that corresponds to the active surface 208a of the chip 208 has a cavity 214. The area of the cavity 214 is big enough to cover the image sensor device 208 (shown in FIG. 6). The surface of the cavity 214 is a smooth surface that has been polished.

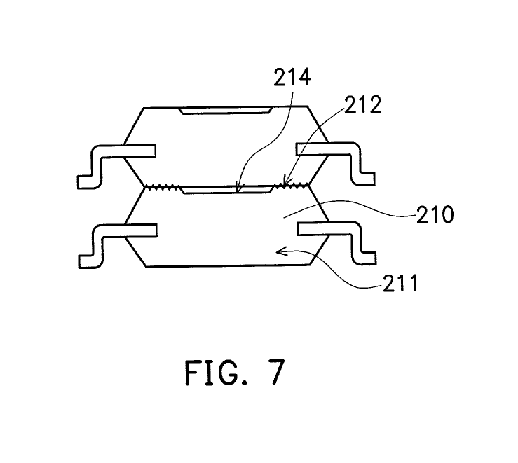

FIG. 7 is a schematic diagram of package of an image sensor device for a post mold cure (PMC) process after completing a molding process according to a first preferred embodiment of the present invention. During the PMC process, the image sensor devices can be stacked up to save space. The characteristic of the present invention is that the cavity surface 214 of the molding surface 212 can reduce abraded damage on the molding surface 212 during the packaging process of the image sensor device 211. Therefore the chance of light being reflected away from the active surface 208a of the chip can be reduced (See FIG. 5). Furthermore, the preferred embodiment of the present invention is not limited to the lead frame, various types of carriers can be utilized, and a plurality of conductive pins can be formed on the carrier.

A Second Preferred Embodiment

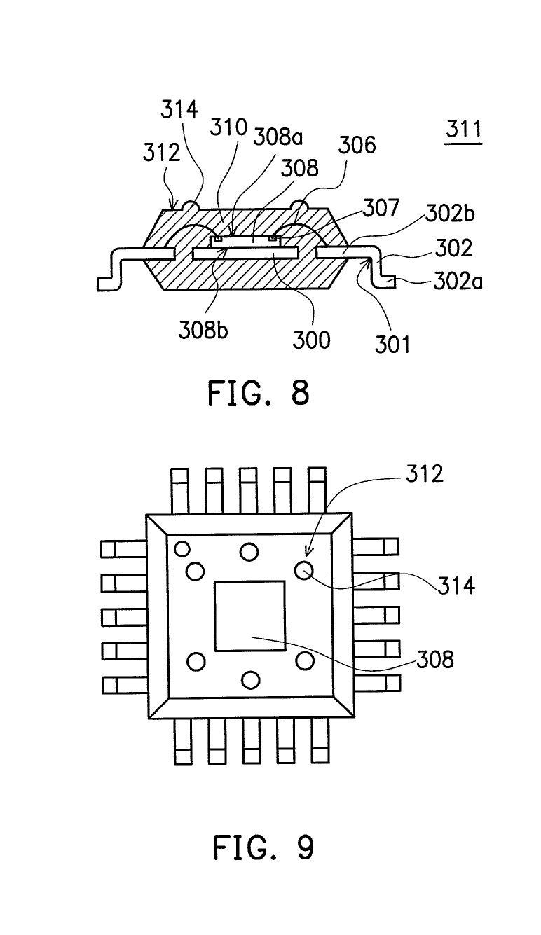

FIG. 8 is a schematic diagram of a package of an image sensor device of a second preferred embodiment according to the present invention, and FIG. 9 is a schematic top view of FIG. 8. Some parts of the device and reference numbers are not shown on FIG. 9, so that the main structure of the device can be seen easily. At least one die pad 300 is in a lead frame 301, a plurality of leads 302 are located at the periphery of the die pad 300. Each lead 302 has an inner lead 302b and an outer lead 302a. An image sensor chip 308 has an active surface 308a and a corresponding back surface 308b. The back surface 308b of the chip is adhered on the die pad 300. The image sensor chip 308 is a complementary metal-oxide semiconductor (CMOS), for example.

A plurality of bonding pads 307 are formed on the active surface 308a of the image sensor chip 308. The bonding pads 307 are electrically connected to the inner lead 302b of the lead 302 by conductive wires 306. The image sensor chip 308, the die pad 300 and the inner lead 302b of the leads 302 are encapsulated by a transparent molding compound 310, for example a transparent resin. A package of an image sensor device 311 is thus completed. A surface of the transparent molding compound 310 that corresponds to the active surface 308a has been polished in order to form a smooth surface 312.

Referring to FIG. 9, the area of the smooth surface 312 is large enough to cover the chip 308 of the image sensor device. A protrusion 314 is formed at the periphery of the smooth surface 312. The protrusion 314 can be, for example, a plurality of node-shaped protrusions, wherein these node-shaped protrusions are located around the periphery of the smooth surface 312. The protrusions 314 of the smooth surface 312 can prevent the damage of abrasion on the smooth surface 312 during the packaging process of the image sensor device 311. Therefore, the light reflection of the active surface 308a of the chip can be reduced.

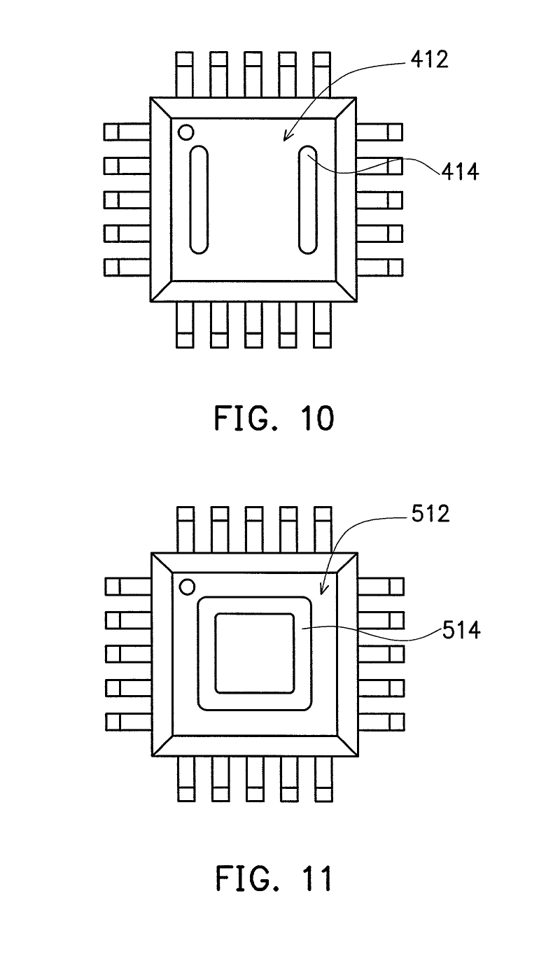

According to the characteristics of the second preferred embodiment of the present invention, the protrusions 314 in FIG. 9 can be made into strip-shaped protrusions that are shown in FIG. 10. The strip-shaped protrusions 414 are located around the periphery of the smooth surface 412 of the molding compound. The protrusions 314 in FIG. 9 also can be made into ring-shaped protrusions that are shown in FIG. 11. The ring-shaped protrusions 514 are located around the periphery of the smooth surface 512 of the molding compound. The second preferred embodiment of the present invention is not limited to the use of the lead frame, various types of carriers can be utilized, and a plurality of connective pins can be formed in the carrier.

The above-mentioned ring-shaped protrusions that are around the periphery of the smooth surface can prevent the abraded damage during the packaging process of the image sensor device in order to reduce the light reflection of the active surface of the chip.

From the preferred embodiments of the present invention, the advantages of the invention are as follows:

1. The present invention provides a packaging comprising a cavity surface of a transparent molding compound in order to prevent abraded damage on a smooth surface during a packaging process of an image sensor device. Furthermore, the light reflection of an active surface of a chip can be reduced.

2. The present invention also provides a packaging comprising a protrusion on the smooth surface of the transparent molding compound in order to prevent the abraded damage on the smooth surface of the molding compound during the packaging process of the image sensor device. Furthermore, the light reflection of the active surface of the chip can be reduced.

The present invention uses a PMC process as an example to explain the abraded damage on the smooth surface during the packaging process of the image sensor device. However, the present invention can also prevent other factors that cause the damage on the smooth surface from contact during packaging.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A package of an image sensor device, the package comprising
a lead frame, comprising a die pad, and a plurality of leads located at the periphery of the die pad, wherein each lead has an inner lead and an outer lead;
a chip of the image sensor having an active surface and a corresponding back surface, wherein a plurality of bonding pads are formed on the active surface, and the back surface of the chip is adhered on the die pad;
a plurality of conductive wires electrically connecting from the bonding pads to the inner leads; and
a transparent molding compound encapsulating the image sensor chip, the die pad and the inner leads, wherein a cavity surface is formed on the transparent molding compound surface that corresponds to the active surface, an area of the cavity is large enough to cover the chip of the image sensor and the cavity surface is polished in order to have a smooth surface.

2. The package of the image sensor device of claim 1,wherein the chip of the image sensor device is a complementary metal-oxide semiconductor.

3. The package of the image sensor device of claim 1, wherein the transparent molding compound is a transparent resin.

4. A package of an image sensor device comprises:
a lead frame, comprising a die pad, and a plurality of leads located at the periphery of the die pad, wherein each lead has an inner lead and an outer lead;
a chip of an image sensor having an active surface and a corresponding back surface, wherein a plurality of bonding pads are formed on the active surface, and the back surface of the chip is adhered on the die pad;
a plurality of conductive wires electrically connecting from the bonding pads to the inner leads; and
a transparent molding compound encapsulating the image sensor chip, the die pad and the inner leads, wherein a surface of the transparent molding compound that corresponds to the active surface is polished to form a smooth surface, an area of the smooth surface is large enough to cover the chip of the image sensor device, and a protrusion is formed at the periphery of the smooth surface.

5. The package of the image sensor device of claim 4, wherein the protrusion is formed by a plurality of node-shaped protrusions located at the periphery of the smooth surface.

6. The package of the image sensor device of claim 4, wherein the protrusion is formed by a plurality of strip-shaped protrusions located at the periphery of the smooth surface.

7. The package of the image sensor device of claim 4, wherein the protrusion can be formed by a plurality of ring-shaped protrusions and they are located at the peripheral of the smooth surface.

8. The package of the image sensor device of claim 4, wherein the chip of the image sensor device is a complementary metal-oxide semiconductor.

9. The package of the image sensor device of claim 4, wherein the transparent molding compound is a transparent resin.

10. A package of an image sensor device, the package comprising:
a carrier having a plurality of conductive pins;
a chip of the image sensor having an active surface and a corresponding back surface, wherein a plurality of bonding pads are formed on the active surface, and the back surface of the chip is adhered on the surface of the carrier;
a plurality of conductive wires electrically connecting from the bonding pads to the conductive pins; and
a transparent molding compound encapsulating the chip of the image sensor, the conductive wires and the conductive pins, wherein a cavity surface is formed on the surface of the transparent molding compound that corresponds to the active surface, an area of the cavity surface is large enough to cover the chip of the image sensor device and the cavity surface is polished to have a smooth surface.

11. The package of the image sensor device of claim 10, wherein the chip of the image sensor device is a complementary metal-oxide semiconductor.

12. The package of the image sensor device of claim 10, wherein the transparent molding compound is a transparent resin.

13. A package of an image sensor device comprises:
a carrier having a plurality of conductive pins;
a chip of the image sensor having an active surface and a corresponding back surface, wherein a plurality of bonding pads are formed on the active surface, and the back surface of the chip is adhered on the surface of the carrier;
a plurality of conductive wires electrically connecting from the bonding pads to the conductive pins; and
a transparent molding compound encapsulating the chip of the image sensor, the conductive wires and the conductive pins, wherein a polished smooth surface is formed on the surface of the transparent molding compound that corresponds to the active surface, an area of the smooth surface is large enough to cover the chip of the image sensor device and a protrusion is formed at the periphery of the smooth surface.

14. The package of the image sensor device of claim 13, wherein the protrusion can be a plurality of node-shaped protrusions, and these node-shaped protrusions are located around the periphery of the smooth surface.

15. The package of the image sensor device of claim 13, wherein the protrusion can be a plurality of strip-shaped protrusions that are located at the periphery of the smooth surface.

16. The package of the image sensor device of claim 13, wherein the protrusion can be a plurality of ring-shaped protrusions that are located at the periphery of the smooth surface.

17. The package of the image sensor device of claim 13, wherein the chip of the image sensor device is a complementary metal-oxide semiconductor.

18. The package of the image sensor device of claim 13, wherein the transparent molding compound is a transparent resin.
